(19) United States
(12) Patent Application Publication
(10) Pub. No.: US 2009/0166324 A1
(43) Pub. Date: Jul. 2, 2009

(54) FULL-WAFER BACKSIDE MARKING PROCESS

(76) Inventor: Kevin J. Lee, Beaverton, OR (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/968,138

(22) Filed: Dec. 31, 2007

(51) Int. Cl. C03C 25/68; C23F 1/00; H01L 21/302; H01L 21/461

(52) U.S. Cl. 216/65; 216/99; 438/707; 257/E21.002; 428/98

(57) ABSTRACT

Embodiments of silicon semiconductor wafers and die having surface marks are described herein. A laser, or other marking tool, may be used to mark, substantially all of a surface of an IC wafer with surface marks, such as microdimples, that camouflage or reduce or eliminate the visibility of any surface imperfections such as smudges, scratches, or other marks that may reduce the marketability of packaged IC's where such surface imperfections are visible to the end customer. By marking the wafer prior to dicing, the entire surface of each individual die may have its entire bottom surface marked. Other embodiments are also described.

### FIELD

This application relates generally to integrated circuit (IC) wafer and die manufacture. In particular, this application relates to improved surface appearance by marking substantially all usable surface of a silicon IC wafer prior to dicing.

### BACKGROUND

Processors for mobile devices, such as laptop computers, often have exposed processor die surfaces due to the space limitations and cooling requirements of mobile devices. Processors for mobile devices are sent to mobile device manufacturers for use in mobile devices. The exposed surface or surfaces of a processor die is often smooth, allowing smudges, light scratches and other surface imperfections to be visible, most of which occur during post-assembly electrical testing and Burn-in. Although visible surface imperfections of this type do not affect processor durability or performance, some customers of some manufacturers return the visually unappealing processors due to poor backside die appearance on mobile processors that do not have an integrated heat spreader to cover up the die backside. Customers return the dies because the poor backside appearance makes it difficult for the customer to perform their own quality assurance checks during their motherboard assembly process, since the customer cannot tell if the poor backside appearance was present as-received or is the result of a problem with their own motherboard assembly process. One attempt to fix the problem involved the use of a coarse-grit backgrind process for a rough surface finish on the backside of the wafer. However, wafers with a coarse backgrind tend to suffer from very high wafer breakage during transportation from one wafer process to another and high die failure rate during dicing and during subsequent manufacturing steps due to the structural damage done to the silicon wafer by grinding.

### BRIEF DESCRIPTION OF THE DRAWINGS

The following description can be better understood in light of Figures, in which:

FIG. 1 illustrates a top view of a IC die with surface imperfections;

FIG. 2 illustrates a top view of an exemplary embodiment of an IC die;

FIG. 3 illustrates a schematic view of an exemplary embodiment of a wafer; and

FIG. 4 illustrates a microscopic view of a surface of an exemplary embodiment of a wafer.

Together with the following description, the Figures demonstrate and explain the principles of the apparatus and methods described herein. In the Figures, the thickness and configuration of components may be exaggerated for clarity. The same reference numerals in different Figures represent the same component.

### DETAILED DESCRIPTION

The following description supplies specific details in order to provide a thorough understanding. Nevertheless, the skilled artisan would understand that the methods and associated processes applying the methods can be implemented and used without employing these specific details. Indeed, the methods and associated processes can be placed into practice by modifying the methods and processes, and can be used in conjunction with any apparatus, process, techniques, methods, etc., conventionally used in the industry. For example, while the description below focuses on modification of Si wafers for use in mobile processors for laptop computers, the methods and processes can be equally applied in other IC applications.

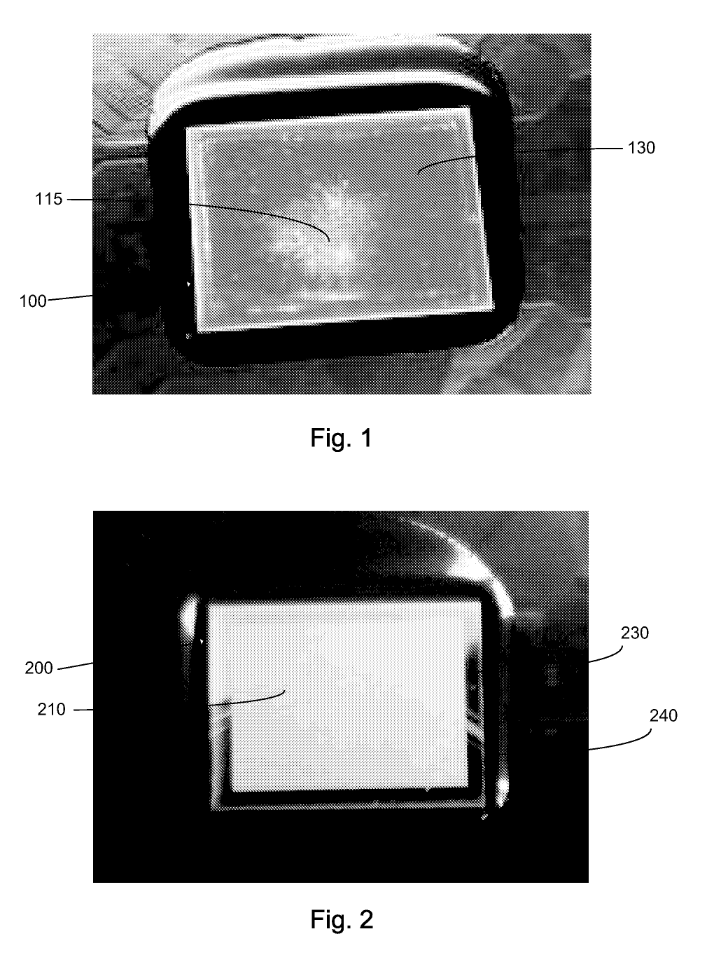

FIG. 1 illustrates conventional die 100 with smooth surface 130 and surface imperfections 115. Surface imperfections 115 may occur at any point during manufacture and assembly of die 100 into an IC package for commercial use. Surface imperfections 115 may render die 100, and by extension the IC package containing die 100, unmarketable although fully functional.

Some embodiments, as illustrated in FIG. 2, may include die 200 with surface marks 210 and smooth surface 230. Smooth surface 230 remains on a periphery of die 200 due to the inability of a marking device, such as a laser, to mark too close to the periphery due to the necessity of not marking any of the epoxy underfill fillet 240 around the perimeter of die 200, since this would compromise the reliability of die 200. Surface marks 210 may be made using a laser. In these embodiments, each die 200 may be processed individually and surface imperfections may still be visible in smooth surface 230.

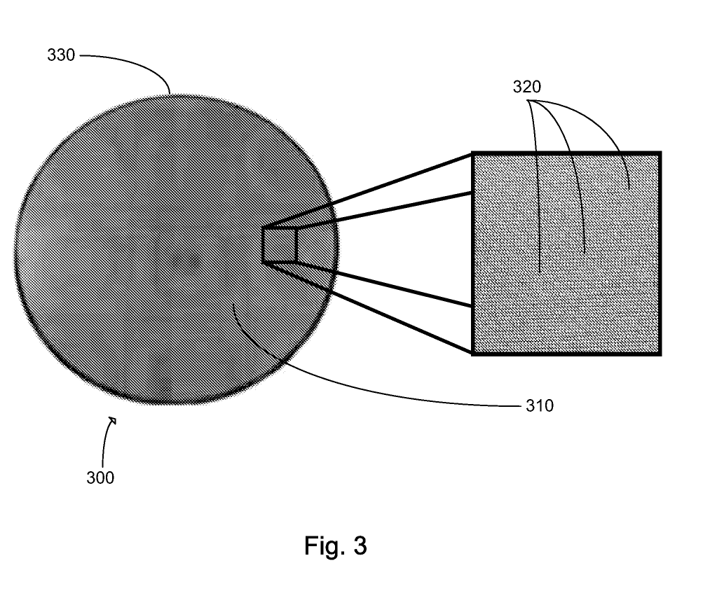

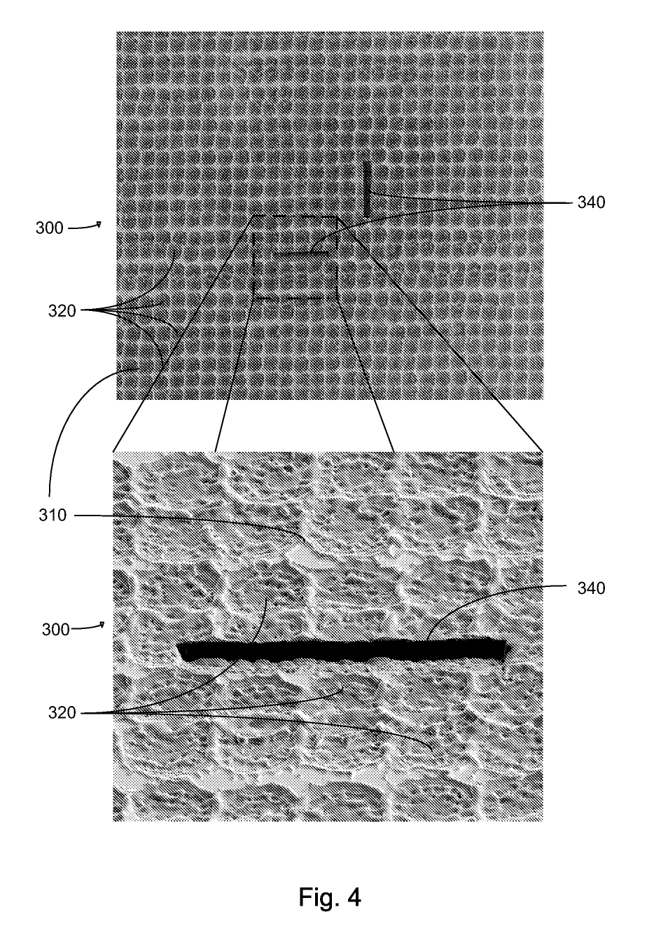

Other embodiments, as illustrated in FIGS. 3 and 4, may include wafer 300 prior to being diced into individual dies. Wafer 300 may be made of Si, or any other material used in IC manufacture as specified by one of ordinary skill. Wafer 300 may include surface marks 310, which may be similar to surface marks 210. As shown in FIG. 4, wafer 300 may also have focused ion beam (FIB) marks 340. FIB may be used in to patch or modify an existing semiconductor or IC device, such as wafer 300. For example, in an IC, a FIB gallium beam could be used to cut unwanted electrical connections, or to deposit conductive material in order to make a connection.

Surface marks 310 may be produced such that the unmagnified marked surface of wafer 300 has a dull surface appearance that is uniform in texture. Surface marks 310 may camouflage or reduce or eliminate susceptibility to surface smudges, scratches, marks, etc. that may limit the marketability of IC packages made from dies cut from wafer 300.

Surface marks 310 may be made of a plurality of individual microdimples 320. Microdimples 320 may be made using a laser. In some embodiments, a laser process, such as a laser for inscribing on IC dies, may be used to mark substantially the entire surface of wafer 300 in a single operation such that hundreds or even thousands of individual dies on wafer 300 may be marked simultaneously, saving time over marking each die individually. Periphery 330 may remain unmarked, for example, because periphery 330 may contain no portion of individual dies to be cut from wafer 300. In some embodiments, microdimples 320 may be placed in a pattern. For example, as shown in FIGS. 3 and 4, individual microdimples 320 may be aligned in rows and columns.

In other embodiments, microdimples 320 may be in an offset pattern, repeating or continuous circular patterns, overlapping one another, or any other pattern such that undesirable surface imperfections are not visible. In some embodiments, microdimples 320 may have a depth of at least about 2 μm. In the illustrated embodiment of FIG. 4, microdimples 320 are shown having a depth of between about 2 and 4 μm, and a circumference of about 70 μm. Microdimples 320 may have a depth and dimension such that the structural integrity of wafer 300 is not compromised sufficiently to increase breakage or failure rates of wafer 300 or dies cut from wafer 300. In embodiments where wafer 300 is made of Si, the marking depth should not exceed about 6 μm to avoid compromising the structural integrity of wafer 300. In some embodiments, the depth and circumference of microdimples 320 may be dependent on the size and type of laser used to mark wafer 300. Similarly, the depth of microdimples 320 may be controlled by adjusting the power, focus, and exposure time of a marking laser used to create surface marks 310.

In some embodiments, surface marks 310 may be a plurality of lines, swirls, zigzags, etc., as desired by one of ordinary skill. Surface marks 310 may also be a continuous line covering the surface of wafer 300 with surface marks 310. In some embodiments, surface marks 310 or microdimples 320 may be any depth or shape sufficient to reduce visible surface imperfections, as described above, without damaging the IC components in wafer 310.

Due to surface marks 310 covering substantially the entire usable surface of wafer 300, when wafer 300 is cut, each of the resulting individual dies may have surface marks 310 extending substantially over its entire surface, eliminating any smooth surface on each individual die that may incur a smudge, scratch, or other undesirable surface imperfection, and improving manufacturing efficiency by marking all dies on a wafer in a single process, rather than marking each die individually. Similarly, surface marks 210, 310 may be made by any process or device that reduces or eliminates susceptibility of die 200 or wafer 300 to surface imperfections that may limit the marketability of an IC package having die 200, or die from wafer 300.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A method, comprising:
marking a surface of a wafer with a plurality of microdimples; and
separating the wafer into a plurality of dies, such that each of the plurality of dies includes a surface substantially entirely marked.

2. The method of claim 1, wherein the marking is done using a laser.

3. The method of claim 1, wherein the marking comprises creating a pattern of microdimples in the surface of the wafer.

4. The method of claim 1, wherein the microdimples are between about 2-6 μm deep.

5. The method of claim 1, wherein the microdimples are between about 2-300 μm wide.

6. The method of claim 1, wherein the marking is configured to create a uniform appearance of the surface of each of the plurality of dies.

7. The method of claim 6, wherein the surface of each of the plurality of dies is resistant to visible surface marking during subsequent manufacturing.

8. The method of claim 1, wherein the wafer is a Si wafer for use in IC manufacture.

9. The method of claim 8, wherein the marking is performed such that the structural integrity of the wafer is substantially maintained.

10. A device, comprising:
a wafer having a top surface and a bottom surface, the top surface including IC components; and
a plurality of features associated with the bottom surface, wherein the plurality of features cover substantially all of the usable space on the bottom surface.

11. The device of claim 10, wherein the wafer is a Si wafer configured to be used in IC manufacture.

12. The device of claim 11, wherein the wafer is configured to be diced into a plurality of IC dies.

13. The device of claim 10, wherein the plurality of features are created using a laser.

14. The device of claim 13, wherein the plurality of features are microdimples.

15. The device of claim 10, wherein the plurality of features are configured to create a uniform appearance of the usable space on the bottom surface.
